(19) United States
(12) Patent Application Publication
(10) Pub. No.: US 2012/0199866 A1
(43) Pub. Date: Aug. 9, 2012

(54) REFLECTIVE ANODE ELECTRODE FOR ORGANIC EL DISPLAY

(75) Inventors: Yumi Iwanari, Kobe-shi (JP); Toshihiro Kugimiya, Kobe-shi (JP); Takayuki Hirano, Kobe-shi (JP); Takeaki Maeda, Kobe-shi (JP)

(73) Assignee: Kabushiki Kaisha Kobe Seiko Sho (Kobe Steel, Ltd.), Kobe-shi (JP)

(21) Appl. No.: 13/502,849

(22) PCT Filed: Nov. 16, 2010
(86) PCT No.: PCT/JP2010/070394

§ 371 Date: Apr. 19, 2012

(30) Foreign Application Priority Data
Nov. 16, 2009 (JP) 2009-261281

(51) Int. Cl. H01L 51/54; C23C 14/14; H01L 23/48

(52) U.S. Cl. 257/98; 257/765; 204/298.13; 257/E51.021; 257/E23.01; 257/40

(57) ABSTRACT

Disclosed is a reflective anode electrode for an organic EL display, which comprises a novel Al-based alloy reflective film. The reflective anode electrode is capable of assuring low contact resistance and high reflectance even in cases where the Al reflective film is in direct contact with an oxide conductive film such as an ITO or IZO film. In addition, when the Al reflective film is formed into a laminated structure together with the oxide conductive film, the work function of the surface of the upper oxide conductive film is equally high with the work function of a laminated structure that is composed of a general-purpose Ag-based alloy film and an oxide conductive film. Specifically disclosed is a reflective anode electrode for an organic EL display, which is formed on a substrate and characterized by comprising a laminated structure that is composed of an Al-based alloy film containing 0.1-6% by atom of Ag and an oxide conductive film that is formed on the Al-based alloy film so as to be in direct contact with the Al-based alloy film.

### TECHNICAL FIELD

The present invention relates to a reflective anode electrode for use in an organic EL display (in particular, a top-emission organic electroluminescent display).

### BACKGROUND ART

An organic electroluminescent (hereinafter, referred to as “organic EL”) display, which is a type of self-luminous flat panel display, is an all solid state flat panel display in which organic EL devices are arranged in a matrix configuration on a substrate such as a glass plate. In an organic EL display, positive electrodes (anodes) and negative electrodes (cathodes) are formed in stripe shapes, and intersections of these electrodes form pixels (organic EL devices). When a current is passed through such organic EL devices by the application of a voltage of several V from an external power supply, the organic molecules are excited to an excited state. The atom then returns to the ground state (the stable state), releasing extra energy in the form of light having a color that is inherent to an individual organic material.

Organic EL devices are self-luminous and electrically driven devices. They have a passive or active driving system. Passive-type devices have a simple structure but are not suited for a full color display. On the other hand, active-type devices can be manufactured in a large size and are suited for a full color display. However, active-type devices involve a TFT substrate. For example, TFT used in such a TFT substrate is low-temperature polycrystalline Si (p-Si) or amorphous Si (a-Si).

In the case of an active-type organic EL display, a plurality of TFTs and wires obstruct so as to reduce the area which can be used for the aperture of organic EL pixels. The influence of such obstacles increases as the drive circuits become more complicated and the number of TFTs is increased. A recent attractive remedy in order to increase the aperture ratio is to configure the structure so as to obtain light from the upper side (top emission) instead of collecting light through a glass substrate.

In a top-emission display, ITO (indium tin oxide) which is excellent in hole injection properties is used to form a lower positive electrode (anode). Although an upper negative electrode (cathode) needs to be formed of a transparent conductive film, ITO is not suited for electron injection because of its high work function. Further, sputtering or ion beam deposition of ITO into a film causes the risk that an electron transport layer (an organic material which forms organic EL devices) will be damaged by plasma ions or secondary electrons during the film formation. In order to prevent such damages and to improve electron injection properties, a thin Mg layer or copper phthalocyanine layer is formed on the electron transport layer.

An anode electrode used in such an active matrix-type, top-emission organic EL display is a multilayer structure (a reflective anode electrode) in which a transparent oxide conductive film typically formed of ITO or IZO (indium zinc oxide) and a reflective film are stacked together, serving a purpose of reflecting light emitted from the organic EL devices. A reflective film that is frequently used in this reflective anode electrode is a reflective metal film formed of molybdenum (Mo), chromium (Cr), aluminum (Al), silver (Ag) or the like. For example, a multilayer structure having ITO and an Ag alloy film has been used as a reflective anode electrode in mass-produced top-emission organic EL displays.

From the viewpoint of reflectance, Ag or an Ag-based alloy containing Ag in a major proportion is useful because of high reflectance. Although an Ag-based alloy is poor in corrosion resistance, this inherent problem is solved by coating the Ag-based alloy film with an ITO film that is stacked on the alloy film. However, Ag is an expensive material and upsizing of a sputtering target which is necessary for film production is difficult. Because of these problems, it is difficult to use an Ag-based alloy film as a reflective film in an active matrix-type, top-emission organic EL display for constituting a large-screen TV.

Meanwhile, Al is also favorable for use as a reflective film if reflectance is the only consideration. For example, PTL 1 discloses an Al film or an Al—Nd film as a reflective film and describes that an Al—Nd film is preferable because of its excellent reflectance efficiency.

However, a direct contact of an Al reflective film with an oxide conductive film such as ITO or IZO results in a high contact resistance so as to make it impossible to supply a current enough to inject holes into the organic EL devices. A remedy to this problem is to replace Al by a high-melting metal such as Mo or Cr or to provide a barrier formed of a high-melting metal such as Mo or Cr between the Al reflective film and the oxide conductive film. However, such a remedy causes a great deterioration in reflectance, resulting in a decrease in emission brightness that is a display characteristic.

In association with this problem, PTL 2 proposes a reflective electrode (a reflective film) eliminating the need of a barrier metal. Namely, an Al—Ni alloy film containing Ni at 0.1 to 2% by atom is disclosed. This Al reflective film has as high a reflectance as that of pure Al and realizes a low contact resistance even when being in direct contact with an oxide conductive film such as ITO or IZO.

### CITATION LIST

### Patent Literature

PTL 1: Japanese Unexamined Patent Application Publication No. 2005-259695

PTL 2: Japanese Unexamined Patent Application Publication No. 2008-122941

### SUMMARY OF INVENTION

### Technical Problem

Here, the injection of holes from a positive electrode (anode) to an upper organic layer in a top-emission organic EL display will be considered. Since holes are injected from the highest occupied molecular orbital (HOMO) of the anode material to HOMO of the organic layer, the difference in energy between these orbitals corresponds to the injection barrier. At the present time, ITO which can reduce the energy barrier has been used in mass production. However, the energy barrier can be increased in the event that the work function of ITO is reduced by any effects caused by the layer lying under ITO. Thus, an underlying metal which does not decrease the work function of ITO is needed. For example, a reflective anode electrode for top-emission organic EL display has a problem in that a multilayer structure composed of an oxide conductive film such as ITO (hereinafter, ITO often represents an oxide conductive film) and an Al reflective film (or an Al alloy reflective film) (upper layer=ITO/lower layer=Al alloy) has a work function of the surface of ITO film that is lower by about 0.1 to 0.2 eV than that in a multilayer structure adopted in currently mass-produced displays (upper layer=ITO/lower layer=Ag-based alloy). Detailed causes for this problem are still unknown. Such a decrease of about 0.1 to 0.2 eV in the work function of the surface of ITO film causes the emission starting voltage (threshold) for an organic emitting layer formed on the ITO film to be shifted by about several volts toward the higher voltage side. Thus, an increased amount of electric power is consumed in order to maintain the same level of emission intensity.

Further, a reflective film is often exposed to an alkaline solution, for example in removing a resist during the film production. Because such exposure tends to cause corrosion (alkali corrosion), a reflective film excellent in resistance to alkali corrosion is desired.

The present invention has been made in view of the art described hereinabove. It is therefore an object of the invention to provide a reflective anode electrode for organic EL display having a novel Al-based alloy reflective film, in which the Al reflective film is in direct contact with an oxide conductive film such as ITO or IZO while ensuring a low contact resistance and a high reflectance and in which the multilayer structure having the reflective film and the oxide conductive film (upper layer=oxide conductive film/lower layer=Al-based alloy) exhibits a work function of the surface of the upper oxide conductive film that is as high as the work function of a general multilayer structure having an Ag-based alloy film and an oxide conductive film (oxide conductive film/Ag-based alloy). An object of the invention that is achieved by a preferred embodiment of the invention is to provide a reflective anode electrode for organic EL display having a novel Al-based alloy reflective film, which further exhibits excellent resistance to corrosion caused by an alkaline solution treatment.

### Solution to Problem

The aspects of the present invention include the following embodiments.

(1) A reflective anode electrode for organic EL display that is formed on a substrate, wherein

the reflective anode electrode includes a multilayer structure that has an Al-based alloy film containing Ag at 0.1 to 6% by atom and an oxide conductive film stacked in direct contact on the Al-based alloy film.

Embodiments of the invention include an embodiment which is directed to the reflective anode electrode for organic EL display that is formed on a substrate according to (1), wherein the reflective anode electrode is a multilayer structure that has an Al-based alloy film containing Ag at 0.1 to 6% by atom and an oxide conductive film stacked in direct contact on the Al-based alloy film.

(2) The reflective anode electrode described in (1), wherein a precipitate or a concentrated layer containing Ag is formed in the interface between the Al-based alloy film and the oxide conductive film.

(3) The reflective anode electrode described in (1) or (2), wherein the Al-based alloy film further contains at least one element selected from the group consisting of La, Ce, Nd, Y, Sm, Ge, Gd and Cu in a total content of 0.1 to 2% by atom, and when the total content of such an element is 1% by atom or more, the element is present as a precipitate.

(4) The reflective anode electrode described in any one of (1) to (3), wherein the oxide conductive film is formed of indium tin oxide (ITO).

(5) The reflective anode electrode described in any one of (1) to (4), wherein the oxide conductive film has a thickness of 5 to 30 nm.

(6) The reflective anode electrode described in any one of (1) to (5), wherein the Al-based alloy film is a film formed by a sputtering method or a vacuum deposition method.

(7) The reflective anode electrode described in any one of (1) to (6), wherein the Al-based alloy film is electrically connected to a source or drain electrode of a thin film transistor formed on the substrate.

(8) A thin film transistor substrate which includes the reflective anode electrode described in any one of (1) to (7).

(9) An organic EL display which includes the thin film transistor substrate described in (8).

(10) An Al-based alloy sputtering target, which is an Al-based alloy sputtering target for forming the Al-based alloy film described in any one of (1) to (7) and which contains Ag at 0.1 to 6% by atom.

(11) The Al-based alloy sputtering target described in (10), which further contains at least one element selected from the group consisting of La, Ce, Nd, Y, Sm, Ge, Gd and Cu in a total content of 0.1 to 2% by atom.

### ADVANTAGEOUS EFFECTS OF INVENTION

According to the invention, an Al-Ag alloy film containing a specific amount of Ag is used as an Al-based alloy reflective film. With this configuration, even a direct contact of the film with an oxide conductive film such as ITO or IZO ensures a low contact resistance and a high reflectance, and the multilayer structure having the reflective film and the oxide conductive film (upper layer=oxide conductive film/lower layer=Al-based alloy) exhibits a work function of the surface of the upper oxide conductive film that is as high as the work function of the surface of an upper oxide conductive film in a general multilayer structure having an Ag-based alloy film and the oxide conductive film (upper layer=oxide conductive film/lower layer=Ag-based alloy). The reflective anode electrode according to the invention enables holes to be injected efficiently into an organic emitting layer, and can efficiently reflect the light emitted from the organic emitting layer by the reflective film. Thus, the inventive reflective anode electrode enables an organic EL display to exhibit excellent emission brightness properties.

Further, the Al-based alloy reflective film may contain Ag and a specific amount of at least one element selected from La, Ce, Nd, Y, Sm, Ge, Gd and Cu (hereinafter, sometimes collectively referred to as X). The use of such an Al—Ag—X alloy film results in a reflective anode electrode for organic EL display which is increased in terms of resistance to alkali corrosion and resistance to heat.

### BRIEF DESCRIPTION OF DRAWING

FIG. 1 is a schematic view illustrating an organic EL display including an inventive reflective anode electrode.

### DESCRIPTION OF EMBODIMENTS

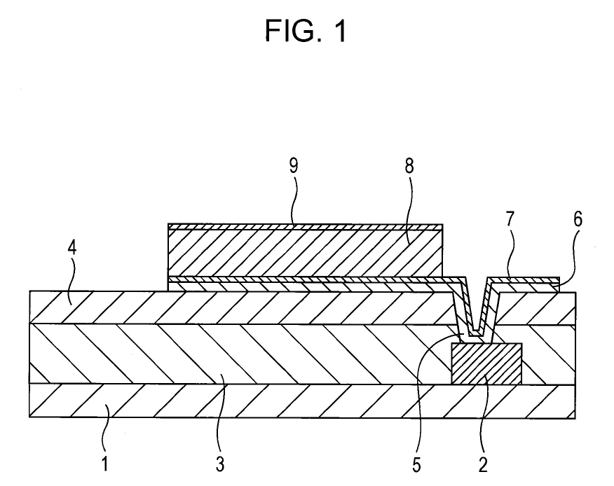

First, an organic EL display including a reflective anode electrode of the invention will be briefly described with reference to FIG. 1. In the following description, an Al—Ag alloy and an Al—Ag—X alloy used in the invention will be sometimes collectively referred to as “Al alloy”.

On a substrate 1, a TFT 2 and a passivation film 3 are formed. Further, a planarization layer 4 is formed on the passivation film. A contact hole 5 is formed on the TFT 2. A source or drain electrode (not shown) of the TFT 2 and an Al alloy film 6 are electrically connected to each other through the contact hole 5.

The Al alloy film is preferably formed by a sputtering method. Preferred sputtering conditions are as follows.

Temperature of substrate: not less than 25° C. and not more than 200° C. (more preferably not more than 150° C.)

Thickness of Al alloy film: not less than 50 nm (more preferably not less than 100 nm) and not more than 300 nm (more preferably not more than 200 nm)

An oxide conductive film 7 is formed directly on the Al alloy film 6. The Al alloy film 6 and the oxide conductive film 7 constitute a reflective anode electrode according to the invention. This multilayer structure is named a reflective anode electrode because the Al alloy film 6 and the oxide conductive film 7 function as a reflective electrode in an organic EL device as well as because they are electrically connected to the source or drain electrode of the TFT 2 so as to serve as an anode electrode.

The oxide conductive film is preferably formed by a sputtering method. Preferred sputtering conditions are as follows.

Temperature of substrate: not less than 25° C. and not more than 150° C. (more preferably not more than 100° C.)

Thickness of oxide conductive film: not less than 5 nm (more preferably not less than 10 nm) and not more than 30 nm (more preferably not more than 20 nm)

An organic emitting layer 8 is formed on the oxide conductive film 7, and a cathode electrode 9 is formed on the organic emitting layer. In this organic EL display configured as described above, the light emitted from the organic emitting layer 8 is efficiently reflected by the inventive reflective anode electrode, thereby realizing excellent emission brightness. A higher reflectance is more preferable. In general, a reflectance of not less than 85%, and preferably not less than 87% is desired.

The following embodiments (I) to (IV) are preferably used in order to form the oxide conductive film in direct contact on the Al alloy film, which is a reflective film.

(I) The Al alloy film is formed.→The oxide conductive film is successively formed. (See Group A in Table 1 described later).

(II) The Al alloy film is formed.→A heat treatment is performed in a vacuum atmosphere or an inert gas (for example, nitrogen) atmosphere at a temperature of not less than 150° C. →The oxide conductive film is formed. In the specification, a heat treatment for the Al alloy film performed prior to the formation of the oxide conductive film will be sometimes referred to as “pre-annealing”. The Al alloy film may be brought into contact with an alkaline solution after the pre-annealing and before the formation of the oxide conductive film. (See Group C in Table 3 described later.)

(III) The Al alloy film is formed.→The oxide conductive film is successively formed.→A heat treatment is performed in a vacuum atmosphere or an inert gas (for example, nitrogen) atmosphere at a temperature of not less than 150° C. (See Group B in Table 2 described later.) In the specification, a heat treatment for the reflective anode electrode (Al alloy film+oxide conductive film) performed after the formation of the oxide conductive film will be sometimes referred to as “post-annealing”.

(IV) The Al alloy film is formed.→The “pre-annealing” is performed.→The oxide conductive film is formed.→The “post-annealing” is performed. Similarly to the embodiment (II), the Al alloy film may be brought into contact with an alkaline solution after the pre-annealing and before the formation of the oxide conductive film. (See Group D in Table 4 described later.)

That is, embodiments according to the invention include an embodiment in which the “pre-annealing” or the “post-annealing” is not performed (namely, no specific heat treatment is carried out) as in the embodiment (I), and an embodiment in which a specific heat treatment(s) is carried out as in the embodiments (II) to (IV). The pre-annealing and the post-annealing may be carried out singly, or both of these heat treatments may be performed. The pre-annealing may be followed by a contact treatment with an alkaline solution.

The effects which are expected by performing the embodiments (II) to (IV) are summarized below.

(II) Pre-annealing . . . Electrical resistivity is reduced. Reflectance is increased

Pre-annealing+alkaline solution treatment . . . Contact resistance is reduced

(III) Post-annealing . . . Electrical resistivity is reduced. Reflectance is increased

(IV) Pre-annealing and post-annealing . . . Electrical resistivity is reduced. Reflectance is increased

Pre-annealing+alkaline solution treatment . . . Contact resistance is reduced

As will be described in detail below, an appropriate embodiment may be adopted from the above embodiments in order to reduce the contact resistance with respect to the oxide conductive film or reduce the electrical resistivity, as well as to increase the reflectance and improve the resistance to corrosion caused by alkaline solutions and the resistance to heat.

The embodiment (I), in which the “pre-annealing” or the “post-annealing” is not performed, will be described. When Al—Ag based alloys containing a predetermined amount of Ag alone are used, for example see samples Nos. 3 to 6 in Table 1, good results are obtained in work function, reflectance, electrical resistivity and heat resistance without performing any heat treatments.

The oxide conductive film may be formed in direct contact on the Al alloy film while maintaining the atmosphere which has been created before the film formation. That is, these films may be formed continuously while maintaining the vacuum or inert gas atmosphere. The same applies to the embodiments (II) to (IV) described below.

In the embodiment (II), the “pre-annealing” is carried out. The pre-annealing results in the formation of a precipitate containing Ag (including the Ag elemental substance as well as intermetallic compounds such as Al₂Ag and AlAg) or a concentrated layer containing such a precipitate in the interface between the Al alloy film and the oxide conductive film, with the result that the contact resistance between the Al alloy film and the oxide conductive film is reduced. The term “concentrated layer” refers to a layer which has an Ag concentration that is relatively higher than the Ag concentration in the Al alloy film. In particular, the pre-annealing treatment is preferably carried out when there is a need for the contact resistance between the Al-based alloy film and the oxide conductive film constituting the reflective anode electrode to be greatly reduced in accordance with the product specification of organic EL display. Further, the formation of such precipitates decreases the electrical resistivity, and the reflectance is correspondingly increased.

When an Al—Ag—X alloy which contains an optional element X is used, the pre-annealing results in the formation of a precipitate containing at least the element X in the interface between the Al—Ag—X alloy film and the oxide conductive film. The addition of the element X provides marked effects in improvements in terms of resistances to heat and alkali corrosion. (Details will be described later.) Further, the formation of element X-containing precipitates reduces the electrical resistivity and increases the reflectance similarly to when the Ag-containing precipitates are formed.

In particular, the above effects obtained by the pre-annealing are noticeable when the total amount of elements X is 1% by atom or more. For example, samples Nos. 8 to 12 containing La as the element X in an amount within the preferred range (0.1 to 2% by atom) according to the invention will be discussed with reference to Table 1 which shows the results obtained “without” any heat treatments. Referring to Table 1, the sample No. 8 or No. 9 containing La at 0.1% by atom or 0.5% by atom was evaluated to be acceptable (evaluation: B) in terms of electrical resistivity even though no heat treatments were performed. On the other hand, the samples Nos. 10 to 12 shown in Table 1 which contained La at 1% by atom or more and which had not been subjected to any heat treatments were evaluated to be unacceptable (evaluation: C) in terms of electrical resistivity (see Table 1). In contrast, the results described in Table 3 show that the pre-annealing of samples Nos. 10 to 12 (the compositions of the Al alloys were identical to those of the samples Nos. 10 to 12 in Table 1) resulted in an acceptable level of electrical resistivity (evaluation: B). Similar tendencies were obtained when the alloy contained an element X other than La. Further, similar tendencies were confirmed not only when the heat treatment pattern belonged to the group described in Table 3, but when the heat treatment pattern belonged to the group described in Table 2 or 4.

In the present invention, the temperature in the pre-annealing is preferably not less than 200° C. At such temperatures, Ag contained in the Al alloy is precipitated. However, a pre-annealing temperature in excess of 300° C. increases the risk that hillocks (knobby bumps) may be formed on the surface of the Al alloy film. Thus, the temperature is preferably not more than 300° C. More preferably, the pre-annealing temperature is in the range of 200° C. to 270° C.

The pre-annealing time is preferably about 10 minutes or more, and more preferably about 15 minutes or more. This pre-annealing time ensures that a desired metal or intermetallic compound is precipitated during the pre-annealing. However, an excessively long pre-annealing time is not desirable from the viewpoint of production efficiency because the step takes a long time. In view of production efficiency and other factors, the pre-annealing time is preferably about 120 minutes or less, and more preferably about 60 minutes or less.

In the invention, the Al alloy film may be subjected to an alkaline solution treatment after the pre-annealing and before the formation of the oxide conductive film. By performing an alkaline solution treatment, the contact resistance between the Al alloy film and the oxide conductive film is markedly reduced. The alkaline solution treatment is not limited as long as an alkaline solution is brought into contact with the surface of the Al alloy film. An exemplary alkaline solution is an aqueous tetramethylammonium hydroxide (TMAH) solution.

A heat treatment that is similar to the pre-annealing carried out in the embodiment (II) may be performed as post-annealing. The pre-annealing and the post-annealing differ only in terms of when the heat treatment is performed, and are the same in terms of conditions in the heat treatment method (for example, atmosphere, temperature and time).

Irrespective of whether the heat treatment is pre-annealing or post-annealing, the formed precipitates enable the reduction of electrical resistivity and the increase of reflectance. On the other hand, different effects work in the reduction in contact resistance with respect to the oxide transparent conductive film. That is, the contact resistance is reduced when both the pre-annealing and the alkaline solution treatment are carried out. Any effects of reducing the contact resistance are not obtained when the post-annealing is performed singly or when the post-annealing and the alkaline solution treatment are carried out. The reason for this difference is because the post-annealing is performed after the oxide transparent conductive film is formed and thus does not change the oxidation state of the interface between the Al alloy film and the transparent conductive film.

Next, the Al alloy film used in the inventive reflective anode electrode will be described.

The Al alloy film contains Ag at 0.1 to 6% by atom. Ag should be added at 0.1% by atom or more in order to reduce the contact resistance with respect to the oxide conductive film as well as to ensure that the multilayer structure composed of the oxide conductive film and the Al alloy film exhibits a work function of the surface of the oxide conductive film that is as high as the work function of a general multilayer structure having an Ag-based alloy. If the Ag content is in excess of 6% by atom, a contact with an alkaline solution results in an increased amount of corrosion originating from the Ag precipitates, thereby causing emission defects of the organic emitting layer. The Ag amount is preferably not less than 0.1% by atom and not more than 6% by atom, and more preferably not less than 0.1% by atom and not more than 4% by atom. These upper and lower limits of the Ag content may be used in any combination.

The Al alloy film may further contain at least one element selected from La, Ce, Nd, Y, Sm, Ge, Gd and Cu (hereinafter, sometimes collectively referred to as X) in a total amount of 0.1 to 2% by atom. The Al alloy film containing such elements achieves an increased heat resistance so as to effectively prevent the formation of hillocks, and is also improved in resistance to corrosion caused by alkaline solutions. A single, or two or more of the elements X may be added.

If the content of elements X (the content of a single element or the total content of two or more elements) is less than 0.1% by atom, the alloy film may not be effectively improved in both of heat resistance and alkali corrosion resistance. If the improvements in these properties are the only consideration, a higher content of elements X is more preferable. However, any content in excess of 2% by atom may cause an increase in the electrical resistivity of the Al alloy film itself. Thus, the content of elements X is preferably not less than 0.1% by atom (more preferably not less than 0.2% by atom) and not more than 2% by atom (more preferably not more than 0.8% by atom). These upper and lower limits of the content of elements X may be used in any combination.

Of the elements X, La, Ce, Gd, Nd, Y and Sm have a higher effect on the improvement of heat resistance, and Ge and Cu are more effective in order to improve the resistance to alkali corrosion. Preferably, two or more of these elements are used in combination. For example, Al—Ag—Cu—Nd alloy or Al—Ag—Ge—Nd alloy may be more preferably used.

In order for the elements X to produce the above effects more effectively, it is preferable that the elements be present as precipitates when the total content of such elements is 1% by atom or more. For example, the pre-annealing and/or the post-annealing described hereinabove can easily cause such elements to be precipitated. In the case where the total content of elements X is less than 1% by atom, satisfactory heat resistance and alkali corrosion resistance can be obtained even when such heat treatments are not carried out (see Nos. 8 and 9 in Table 1).

The Al alloy film in the invention may be an Al alloy film which contains a predetermined amount of Ag and a balance of Al and inevitable impurities, or may be an Al alloy film which further contains a predetermined amount of element(s) X and a balance of Al and inevitable impurities.

Examples of inevitable impurities include elements that are inevitably mixed during the production process, such as Fe, Cu, C, O and N.

The Al alloy film used in the invention has been described hereinabove.

The Al alloy film is preferably formed by a sputtering method or a vacuum deposition method, and particularly preferably produced by using a sputtering target (hereinafter, sometimes referred to as “target”) according to a sputtering method. According to a sputtering method, a thin film which is excellent in terms of uniformity of component distribution and uniformity of film thickness within the film can be formed easily compared to when the film is produced by an ion plating method or an electron beam deposition method.

The Al alloy film may be formed by a sputtering method using an Al alloy sputtering target which contains the aforementioned elements (Ag, and preferably the element(s) X) and has the same composition as that in the desired Al alloy film. The use of such a target is advantageous in that differences in composition may be prevented and an Al alloy film having a desired composition of components may be formed.

Accordingly, the aspects according to the present invention include a sputtering target having the same composition as that of the aforementioned Al alloy film. In detail, examples of the sputtering targets according to an aspect of the invention include an Al alloy sputtering target containing Ag at 0.1 to 6% by atom (preferably 0.1 to 4% by atom) and a balance of Al and inevitable impurities, and an Al alloy sputtering target containing Ag at 0.1 to 6% by atom (preferably 0.1 to 4% by atom), the elements X in a total content of 0.1 to 2% by atom (wherein the lower limit is preferably 0.2% by atom, and the upper limit is preferably 0.8% by atom) and a balance of Al and inevitable impurities.

The target may be processed into any shape (for example, a square plate shape, a circular plate shape, or a doughnut-plate shape) in accordance with the shape or the structure of a sputtering apparatus.

Exemplary methods for fabricating the target include a method in which an ingot of an Al-based alloy is produced by melt casting, powder sintering or spray forming and the ingot is processed into the target, and a method in which a preform composed of an Al-based alloy (an intermediate for a dense final product) is prepared and the preform is densified by densification means.

The oxide conductive film used in the invention is not particularly limited and may be any of commonly used films such as indium tin oxide (ITO) and indium zinc oxide (IZO). Indium tin oxide is preferable.

The thickness of the oxide conductive film is preferably 5 to 30 nm. If the thickness of the oxide conductive film is less than 5 nm, a pinhole may be formed in the ITO film so as to possibly cause a dark spot. On the other hand, a decrease in reflectance may be caused if the thickness of the oxide conductive film exceeds 30 nm. The thickness of the oxide conductive film is more preferably not less than 5 nm and not more than 20 nm. These upper and lower limits of the thickness of the oxide conductive film may be used in any combination.

The reflective anode electrode for organic EL display according to the present invention has excellent reflectance and low contact resistance. In addition, the multilayer structure including the oxide transparent conductive film exhibits a work function of the upper oxide transparent conductive film that is controlled so as to be substantially equal to the work function of a general multilayer structure having an Ag-based alloy. According to a preferred embodiment of the invention, the reflective anode electrode further achieves excellent resistances to alkali corrosion and heat. Thus, the inventive reflective anode electrode is preferably used in a thin film transistor substrate, and further in a display device (for example, an organic EL display).

### EXAMPLES

The present invention will be described in greater detail by presenting examples below. However, the scope of the invention is not limited to such examples, and modifications may be made without departing from the spirit of the invention described hereinabove and hereinbelow. Such modifications are also included in the technical scope of the present invention.

### EXAMPLE 1

In this example, various kinds of Al alloy reflective films were used and studies were made in order to examine how performing no heat treatment (Group A, Table 1) or performing post-annealing (Group B, Table 2) would affect the work function, the reflectance and the electrical resistivity, as well as the heat resistance, which is a property achieved according to a preferred embodiment of the invention.

First, an alkali-free glass plate (plate thickness: 0.7 mm) as a substrate was provided, and a SiN passivation film (film thickness: 300 nm) was formed on the surface of the substrate with a plasma CVD apparatus. The film production conditions were substrate temperature: 280° C., gas ratio: SiH₄/NH₃/N₂=125/6/185, pressure: 137 Pa, and RF power: 100 W. On the surface of the passivation film, an Al alloy film which was a reflective film (film thickness: about 100 nm) was formed by a sputtering method. The compositions of the Al alloy films are described in Tables 1 and 2. The film production conditions were substrate temperature: 25° C., pressure: 2 mToor, and DC power: 260 W. For comparison, a pure Al film (film thickness: about 100 nm) and an Al-0.6% by atom Nd (film thickness: about 100 nm) which was a simulated alloy film according to PTL 1 were also formed by a sputtering method under similar conditions. The compositions of the reflective films were measured by ICP emission analysis.

The reflective films produced in the above manner were grouped into Group A and Group B. With respect to the films belonging to Group A, an ITO film was formed. The films belonging to Group B were subjected to a processing in order to form an ITO film and were thereafter heat treated (post-annealed) at 250° C. in a nitrogen atmosphere for 30 minutes.

In the production of the ITO film, the vacuum atmosphere was continuously used without releasing the vacuum to the outside air, and an ITO film having a thickness of 10 nm was produced by a sputtering method, thereby producing a reflective anode electrode (reflective film+oxide conductive film). The film production conditions were substrate temperature: 25° C., pressure: 0.8 mToor, and DC power: 150 W.

Each of the reflective anode electrodes produced as described above was tested by the following methods in order to evaluate (1) the work function of the surface of the ITO film, (2) the reflectance, (3) the electrical resistivity of the Al alloy and (4) the heat resistance (surface anomalies such as hillocks).

### (1) Work Function of Surface of ITO Film

The work function of the surface of the ITO film was measured using AC-2 manufactured by RIKEN KEIKI Co., Ltd. Because the surface work function is sensitive to the surface state (for example, contamination with organic substances in the atmosphere), the surface was exposed to UV ozone immediately before the measurement with AC-2. For comparison, the work function was measured in a similar manner with respect to a multilayer structure produced using Ag-0.7% by atom Pd-1% by atom Cu which was a typical mass-produced Ag-based alloy.

On the basis of the measured values of the ITO/Ag-based alloy structure (4.9 to 5.0 eV), the work function was evaluated based on the following criteria.

A: 4.9 eV or more

B: less than 4.9 eV

### (2) Reflectance

To evaluate the reflectance, the spectral reflectivity was measured at a wavelength of 1000 to 250 nm using visible UV spectrophotometer “V-570” manufactured by JASCO Corporation. In detail, a percentage of the intensity of light reflected by the sample relative to the intensity of light reflected by a standard mirror was obtained as “reflectance”. Here, the reflectance was a value measured after the ITO film was formed. With respect to the films belonging to Group B, the reflectance was a value measured after the post-annealing.

In this example, the reflectance was evaluated relative to the reflectance at λ=550 nm as the standard, and the samples evaluated A or B were determined to be acceptable.

A: 87% or more

B: 80% to less than 87%

C: less than 80%

### (3) Electrical Resistivity of Al Alloy

The electrical resistivity of the Al alloy was measured by a four-terminal method. In this example, the electrical resistivity was evaluated on the basis of the following criteria. The samples evaluated A or B were determined to be acceptable.

A: less than 5 μΩcm

B: 5 μΩcm to less than 7μΩcm

C: 7 μΩcm or more

### (4) Heat Resistance

The heat resistance was evaluated by observing the surface of the reflective anode electrode with an optical microscope (×500 magnification). Hillocks which were observed as black dots were counted. In this example, the heat resistance was evaluated on the basis of 1×10⁹ hillocks/m². The samples evaluated A were determined to be acceptable.

A: hillock density<1×10⁹ hillocks/m²

B: hillock density≧1×10⁹ hillocks/m²

The results are described in Tables 1 and 2.

TABLE 1

| | Composition of | | | Post- | Work | | Electrical | Heat |
|---|---|---|---|---|---|---|---|---|
| No. | reflective film* | Inclusion** | Group | annealing | function | Reflectance | resistivity | resistance |
| 1 | Pure Al | — | A | No | B | A | A | A |
| 2 | Al—0.6Nd | — | A | No | B | B | C | A |
| 3 | Al—0.1Ag | — | A | No | A | A | A | A |
| 4 | Al—0.6Ag | — | A | No | A | A | A | A |
| 5 | Al—2Ag | — | A | No | A | B | B | A |
| 6 | Al—6Ag | — | A | No | A | B | B | A |
| 7 | Al—8Ag | — | A | No | A | C | B | A |
| 8 | Al—0.1Ag—0.1La | Absent | A | No | A | A | B | A |
| 9 | Al—0.6Ag—0.5La | Absent | A | No | A | B | B | A |
| 10 | Al—1Ag—1La | Absent | A | No | A | B | C | A |
| 11 | Al—2Ag—2La | Absent | A | No | A | B | C | A |
| 12 | Al—6Ag—2La | Absent | A | No | A | B | C | A |
| 13 | Al—6Ag—3La | Absent | A | No | A | B | C | A |
| 14 | Al—0.1Ag—0.1Ce | Absent | A | No | A | A | B | A |
| 15 | Al—0.6Ag—0.5Ce | Absent | A | No | A | B | B | A |
| 16 | Al—1Ag—1Ce | Absent | A | No | A | B | C | A |
| 17 | Al—2Ag—2Ce | Absent | A | No | A | B | C | A |
| 18 | Al—6Ag—2Ce | Absent | A | No | A | B | C | A |
| 19 | Al—0.1Ag—0.1Nd | Absent | A | No | A | B | B | A |
| 20 | Al—0.6Ag—0.5Nd | Absent | A | No | A | A | B | A |
| 21 | Al—1Ag—1Nd | Absent | A | No | A | B | C | A |
| 22 | Al—2Ag—2Nd | Absent | A | No | A | B | C | A |
| 23 | Al—6Ag—2Nd | Absent | A | No | A | B | C | A |
| 24 | Al—0.1Ag—0.1Y | Absent | A | No | A | B | B | A |
| 25 | Al—0.6Ag—0.5Y | Absent | A | No | A | B | B | A |
| 26 | Al—1Ag—1Y | Absent | A | No | A | A | C | A |
| 27 | Al—2Ag—2Y | Absent | A | No | A | B | C | A |
| 28 | Al—6Ag—2Y | Absent | A | No | A | B | C | A |
| 29 | Al—0.1Ag—0.1Sm | Absent | A | No | A | B | B | A |
| 30 | Al—0.6Ag—0.5Sm | Absent | A | No | A | B | B | A |
| 31 | Al—1Ag—1Sm | Absent | A | No | A | B | C | A |
| 32 | Al—2Ag—2Sm | Absent | A | No | A | A | C | A |
| 33 | Al—6Ag—2Sm | Absent | A | No | A | B | C | A |
| 34 | Al—0.1Ag—0.1Ge | Absent | A | No | A | B | B | A |
| 35 | Al—0.6Ag—0.5Ge | Absent | A | No | A | B | B | A |
| 36 | Al—1Ag—1Ge | Absent | A | No | A | B | B | A |
| 37 | Al—2Ag—2Ge | Absent | A | No | A | B | C | A |
| 38 | Al—6Ag—2Ge | Absent | A | No | A | A | C | A |
| 39 | Al—0.1Ag—0.1Cu | Absent | A | No | A | B | A | A |
| 40 | Al—0.6Ag—0.5Cu | Absent | A | No | A | B | A | A |
| 41 | Al—1Ag—1Cu | Absent | A | No | A | B | B | A |
| 42 | Al—2Ag—2Cu | Absent | A | No | A | B | B | A |
| 43 | Al—6Ag—2Cu | Absent | A | No | A | B | C | A |
| 44 | Al—0.6Ag—0.5Cu—0.5Nd | Absent | A | No | A | B | B | A |
| 45 | Al—0.6Ag—0.5Ge—0.5Nd | Absent | A | No | A | B | B | A |

*Unit of composition of components: % by atom, Balance: Al and inevitable impurities
**Inclusion means any inclusion containing elements X, and the hyphen “—” means that the measurement was not carried out because no elements X were added.

TABLE 2

| | Composition of | | | Post-annealing | Work | | Electrical | Heat |
|---|---|---|---|---|---|---|---|---|
| No. | reflective film* | Inclusion** | Group | temperature | function | Reflectance | resistivity | resistance |
| 1 | Pure Al | — | B | 250° C., 30mim | B | A | A | B |
| 2 | Al—0.6Nd | — | B | 250° C., 30mim | B | A | B | A |
| 3 | Al—0.1Ag | — | B | 250° C., 30mim | A | A | A | B |
| 4 | Al—0.6Ag | — | B | 250° C., 30mim | A | A | A | B |
| 5 | Al—2Ag | — | B | 250° C., 30mim | A | B | B | B |
| 6 | Al—6Ag | — | B | 250° C., 30mim | A | B | B | B |
| 7 | Al—8Ag | — | B | 250° C., 30mim | A | B | B | B |
| 8 | Al—0.1Ag—0.1La | Present | B | 250° C., 30mim | A | A | A | A |
| 9 | Al—0.6Ag—0.5La | Present | B | 250° C., 30mim | A | A | A | A |
| 10 | Al—1Ag—1La | Present | B | 250° C., 30mim | A | B | B | A |
| 11 | Al—2Ag—2La | Present | B | 250° C., 30mim | A | B | B | A |
| 12 | Al—6Ag—2La | Present | B | 250° C., 30mim | A | B | B | A |
| 13 | Al—6Ag—3La | Present | B | 250° C., 30mim | A | B | C | A |
| 14 | Al—0.1Ag—0.1Ce | Present | B | 250° C., 30mim | A | A | A | A |
| 15 | Al—0.6Ag—0.5Ce | Present | B | 250° C., 30mim | A | A | A | A |
| 16 | Al—1Ag—1Ce | Present | B | 250° C., 30mim | A | B | B | A |
| 17 | Al—2Ag—2Ce | Present | B | 250° C., 30mim | A | B | B | A |
| 18 | Al—6Ag—2Ce | Present | B | 250° C., 30mim | A | B | B | A |
| 19 | Al—0.1Ag—0.1Nd | Present | B | 250° C., 30mim | A | A | A | A |
| 20 | Al—0.6Ag—0.5Nd | Present | B | 250° C., 30mim | A | A | A | A |
| 21 | Al—1Ag—1Nd | Present | B | 250° C., 30mim | A | B | B | A |
| 22 | Al—2Ag—2Nd | Present | B | 250° C., 30mim | A | B | B | A |
| 23 | Al—6Ag—2Nd | Present | B | 250° C., 30mim | A | B | B | A |
| 24 | Al—0.1Ag—0.1Y | Present | B | 250° C., 30mim | A | B | A | A |
| 25 | Al—0.6Ag—0.5Y | Present | B | 250° C., 30mim | A | B | A | A |
| 26 | Al—1Ag—1Y | Present | B | 250° C., 30mim | A | A | B | A |
| 27 | Al—2Ag—2Y | Present | B | 250° C., 30mim | A | B | B | A |
| 28 | Al—6Ag—2Y | Present | B | 250° C., 30mim | A | B | B | A |
| 29 | Al—0.1Ag—0.1Sm | Present | B | 250° C., 30mim | A | A | A | A |
| 30 | Al—0.6Ag—0.5Sm | Present | B | 250° C., 30mim | A | B | A | A |
| 31 | Al—1Ag—1Sm | Present | B | 250° C., 30mim | A | B | B | A |
| 32 | Al—2Ag—2Sm | Present | B | 250° C., 30mim | A | A | B | A |
| 33 | Al—6Ag—2Sm | Present | B | 250° C., 30mim | A | B | B | A |
| 34 | Al—0.1Ag—0.1Ge | Present | B | 250° C., 30mim | A | A | A | A |
| 35 | Al—0.6Ag—0.5Ge | Present | B | 250° C., 30mim | A | A | A | A |
| 36 | Al—1Ag—1Ge | Present | B | 250° C., 30mim | A | B | B | A |
| 37 | Al—2Ag—2Ge | Present | B | 250° C., 30mim | A | B | B | A |
| 38 | Al—6Ag—2Ge | Present | B | 250° C., 30mim | A | A | B | A |
| 39 | Al—0.1Ag—0.1Cu | Present | B | 250° C., 30mim | A | A | A | A |
| 40 | Al—0.6Ag—0.5Cu | Present | B | 250° C., 30mim | A | A | A | A |
| 41 | Al—1Ag—1Cu | Present | B | 250° C., 30mim | A | A | B | A |
| 42 | Al—2Ag—2Cu | Present | B | 250° C., 30mim | A | B | B | A |
| 43 | Al—6Ag—2Cu | Present | B | 250° C., 30mim | A | B | B | A |
| 44 | Al—0.6Ag—0.5Cu—0.5Nd | Present | B | 250° C., 30mim | A | A | B | A |
| 45 | Al—0.6Ag—0.5Ge—0.5Nd | Present | B | 250° C., 30mim | A | A | B | A |

*Unit of composition of components: % by atom, Balance: Al and inevitable impurities
**Inclusion means any inclusion containing elements X, and the hyphen “—” means that the measurement was not carried out because no elements X were added.

Table 1 show the results of the samples which were not heat treated. Good results were obtained in all the work function, the reflectance, the electrical resistivity and the heat resistance when the used Al alloy film satisfied the requirements according to the invention. In the samples Nos. 10 to 13, 16 to 18, 21 to 23, 26 to 28, 31 to 33, 37, 38 and 43 in Table 1 which contained an element X at 1% by atom or more, any precipitates containing such an element were not formed because these samples were not heat treated. As a result, the electrical resistivity was unsatisfactory.

Referring to Table 1, the samples Nos. 3 to 7 involved an Al—Ag alloy containing Ag alone in the amount according to the invention. As described in Table 1 (no heat treatment), these samples exhibited good heat resistance, which is a property achieved according to a preferred embodiment of the invention. However, corresponding samples showed a decreased heat resistance in Table 2 (when post-annealing was performed). From these results, it is recommended that post-annealing be not carried out when the Al—Ag alloy contains no elements X and high heat resistance is needed.

### EXAMPLE 2

In this example, Al alloy reflective films having the same compositions as in EXAMPLE 1 were used and studies were made in order to examine how performing pre-annealing and alkaline solution treatment (Group C, Table 3) or performing pre-annealing, alkaline solution treatment and post-annealing (Group D, Table 4) would affect the work function, the reflectance, the electrical resistivity and the contact resistance, as well as the heat resistance and the alkali corrosion resistance, which are properties achieved according to a preferred embodiment of the invention.

First, reflective films were produced in the same manner as described in EXAMPLE 1. The produced reflective films were grouped into Group C and Group D. The films belonging to Group C were heat treated (pre-annealed) at 250° C. for 30 minutes in a nitrogen atmosphere and were thereafter subjected to an alkaline solution treatment (a TMAH treatment) in which the films were soaked in an alkaline solution that was an aqueous tetramethylammonium hydroxide (TMAH) solution having a concentration of 0.4% by mass for 20 seconds. Thereafter, an ITO film was produced in the same manner as described in EXAMPLE 1. The films belonging to Group D were treated similarly to the Group C films, an ITO film was produced, and the obtained samples were post-annealed similarly to the Group B samples.

The reflective anode electrodes manufactured as described above were tested by the same methods described in EXAMPLE 1 in order to evaluate (1) the work function of the surface of the ITO film, (2) the reflectance, (3) the electrical resistivity of the Al alloy and (4) the heat resistance (surface anomalies such as hillocks). In addition, (5) the contact resistance with respect to the ITO film and (6) the alkali corrosion resistance were evaluated.

### (5) Contact Resistance

The heat-treated sample belonging to Group C or Group D was etched so as to form a contact resistance measurement pattern (contact area: 20, 40 or 80 μm^{□}). The contact resistance of the sample was measured by a four-terminal Kelvin method. The average of the contact resistance values measured under these three conditions was calculated and was converted to the contact resistance corresponding to a contact area of 10 μm^{□}. In this example, the contact resistance was evaluated on the basis of the following criteria. The samples evaluated A were determined to be acceptable.

A: contact resistance<1 kΩ

B: contact resistance≧1 kΩ

### (6) Alkali Corrosion Resistance (Corrosion Resistance in the Tables)

Immediately after the Al alloy film (the reflective film) was subjected to the alkaline solution treatment, the surface of the Al alloy film was observed with an optical microscope (×1000 magnification). Black dots were regarded as corroded spots originating from precipitates. The smallest size (equivalent circle diameter) of the corroded spot which was recognizable by optical microscope observation was measured to be 130 nm by SEM observation. In the optical microscope observation, the average of the numbers of corroded spots observed in 10 fields (one field was 140 μm×100 μm) per 10 μm^{□} was calculated. The alkali corrosion resistance was evaluated on the basis of the following criteria. The samples evaluated A were determined to be acceptable.

A: less than 1

B: 1 or more

The results are described in Tables 3 and 4.

TABLE 3

| | Composition of | | | | Work | | Electrical | Heat | Contact | Corrosion |
|---|---|---|---|---|---|---|---|---|---|---|
| No. | reflective film* | Inclusion** | Group | Post-annealing | function | Reflectance | resistivity | resistance | resistance | resistance |
| 1 | Pure Al | — | C | No | B | A | A | B | B | A |
| 2 | Al—0.6Nd | — | C | No | B | B | B | A | B | A |
| 3 | Al—0.1Ag | — | C | No | A | A | A | B | A | A |
| 4 | Al—0.6Ag | — | C | No | A | A | A | B | A | B |
| 5 | Al—2Ag | — | C | No | A | B | B | B | A | B |
| 6 | Al—6Ag | — | C | No | A | B | B | B | A | B |
| 7 | Al—8Ag | — | C | No | A | B | B | B | A | B |
| 8 | Al—0.1Ag—0.1La | Present | C | No | A | A | A | A | A | A |
| 9 | Al—0.6Ag—0.5La | Present | C | No | A | A | A | A | A | A |
| 10 | Al—1Ag—1La | Present | C | No | A | B | B | A | A | A |
| 11 | Al—2Ag—2La | Present | C | No | A | B | B | A | A | A |
| 12 | Al—6Ag—2La | Present | C | No | A | B | B | A | A | A |
| 13 | Al—6Ag—3La | Present | C | No | A | B | C | A | A | A |
| 14 | Al—0.1Ag—0.1Ce | Present | C | No | A | A | A | A | A | A |
| 15 | Al—0.6Ag—0.5Ce | Present | C | No | A | A | A | A | A | A |
| 16 | Al—1Ag—1Ce | Present | C | No | A | B | B | A | A | A |
| 17 | Al—2Ag—2Ce | Present | C | No | A | B | B | A | A | A |
| 18 | Al—6Ag—2Ce | Present | C | No | A | B | B | A | A | A |
| 19 | Al—0.1Ag—0.1Nd | Present | C | No | A | A | A | A | A | A |
| 20 | Al—0.6Ag—0.5Nd | Present | C | No | A | A | A | A | A | A |
| 21 | Al—1Ag—1Nd | Present | C | No | A | B | B | A | A | A |
| 22 | Al—2Ag—2Nd | Present | C | No | A | B | B | A | A | A |
| 23 | Al—6Ag—2Nd | Present | C | No | A | B | B | A | A | A |
| 24 | Al—0.1Ag—0.1Y | Present | C | No | A | A | A | A | A | A |
| 25 | Al—0.6Ag—0.5Y | Present | C | No | A | A | A | A | A | A |
| 26 | Al—1Ag—1Y | Present | C | No | A | A | B | A | A | A |
| 27 | Al—2Ag—2Y | Present | C | No | A | B | B | A | A | A |
| 28 | Al—6Ag—2Y | Present | C | No | A | B | B | A | A | A |
| 29 | Al—0.1Ag—0.1Sm | Present | C | No | A | A | A | A | A | A |
| 30 | Al—0.6Ag—0.5Sm | Present | C | No | A | A | A | A | A | A |
| 31 | Al—1Ag—1Sm | Present | C | No | A | B | B | A | A | A |
| 32 | Al—2Ag—2Sm | Present | C | No | A | A | B | A | A | A |
| 33 | Al—6Ag—2Sm | Present | C | No | A | B | B | A | A | A |
| 34 | Al—0.1Ag—0.1Ge | Present | C | No | A | A | A | A | A | A |
| 35 | Al—0.6Ag—0.5Ge | Present | C | No | A | A | A | A | A | A |
| 36 | Al—1Ag—1Ge | Present | C | No | A | B | B | A | A | A |
| 37 | Al—2Ag—2Ge | Present | C | No | A | B | B | A | A | A |
| 38 | Al—6Ag—2Ge | Present | C | No | A | A | B | A | A | A |
| 39 | Al—0.1Ag—0.1Cu | Present | C | No | A | A | A | A | A | A |
| 40 | Al—0.6Ag—0.5Cu | Present | C | No | A | A | A | A | A | A |
| 41 | Al—1Ag—1Cu | Present | C | No | A | A | B | A | A | A |
| 42 | Al—2Ag—2Cu | Present | C | No | A | B | B | A | A | A |
| 43 | Al—6Ag—2Cu | Present | C | No | A | B | B | A | A | A |
| 44 | Al—0.6Ag—0.5Cu—0.5Nd | Present | C | No | A | A | B | A | A | A |
| 45 | Al—0.6Ag—0.5Ge—0.5Nd | Present | C | No | A | A | B | A | A | A |

*Unit of composition of components: % by atom, Balance: Al and inevitable impurities
**Inclusion means any inclusion containing elements X, and the hyphen “—” means that the measurement was not carried out because no elements X were added.

TABLE 4

| | | | | Post- | | | | | Contact | |
|---|---|---|---|---|---|---|---|---|---|---|
| | Composition of | | | annealing | Work | | Electrical | Heat | resis- | Corrosion |
| No. | reflective film* | Inclusion** | Group | temperature | function | Reflectance | resistivity | resistance | tance | resistance |
| 1 | Pure Al | — | D | 250° C., 30mim | B | A | A | B | B | A |
| 2 | Al—0.6Nd | — | D | 250° C., 30mim | B | A | B | A | B | A |
| 3 | Al—0.1Ag | — | D | 250° C., 30mim | A | A | A | B | A | A |
| 4 | Al—0.6Ag | — | D | 250° C., 30mim | A | A | A | B | A | B |
| 5 | Al—2Ag | — | D | 250° C., 30mim | A | B | B | B | A | B |
| 6 | Al—6Ag | — | D | 250° C., 30mim | A | B | B | B | A | B |
| 7 | Al—8Ag | — | D | 250° C., 30mim | A | B | B | B | A | B |
| 8 | Al—0.1Ag—0.1La | Present | D | 250° C., 30mim | A | A | A | A | A | A |
| 9 | Al—0.6Ag—0.5La | Present | D | 250° C., 30mim | A | A | A | A | A | A |
| 10 | Al—1Ag—1La | Present | D | 250° C., 30mim | A | B | B | A | A | A |
| 11 | Al—2Ag—2La | Present | D | 250° C., 30mim | A | B | B | A | A | A |
| 12 | Al—6Ag—2La | Present | D | 250° C., 30mim | A | B | B | A | A | A |
| 13 | Al—6Ag—3La | Present | D | 250° C., 30mim | A | B | C | A | A | A |
| 14 | Al—0.1Ag—0.1Ce | Present | D | 250° C., 30mim | A | A | A | A | A | A |
| 15 | Al—0.6Ag—0.5Ce | Present | D | 250° C., 30mim | A | A | A | A | A | A |
| 16 | Al—1Ag—1Ce | Present | D | 250° C., 30mim | A | B | B | A | A | A |
| 17 | Al—2Ag—2Ce | Present | D | 250° C., 30mim | A | B | B | A | A | A |
| 18 | Al—6Ag—2Ce | Present | D | 250° C., 30mim | A | B | B | A | A | A |
| 19 | Al—0.1Ag—0.1Nd | Present | D | 250° C., 30mim | A | A | A | A | A | A |
| 20 | Al—0.6Ag—0.5Nd | Present | D | 250° C., 30mim | A | A | A | A | A | A |
| 21 | Al—1Ag—1Nd | Present | D | 250° C., 30mim | A | B | B | A | A | A |
| 22 | Al—2Ag—2Nd | Present | D | 250° C., 30mim | A | B | B | A | A | A |
| 23 | Al—6Ag—2Nd | Present | D | 250° C., 30mim | A | B | B | A | A | A |
| 24 | Al—0.1Ag—0.1Y | Present | D | 250° C., 30mim | A | A | A | A | A | A |
| 25 | Al—0.6Ag—0.5Y | Present | D | 250° C., 30mim | A | A | A | A | A | A |
| 26 | Al—1Ag—1Y | Present | D | 250° C., 30mim | A | A | B | A | A | A |
| 27 | Al—2Ag—2Y | Present | D | 250° C., 30mim | A | B | B | A | A | A |
| 28 | Al—6Ag—2Y | Present | D | 250° C., 30mim | A | B | B | A | A | A |
| 29 | Al—0.1Ag—0.1Sm | Present | D | 250° C., 30mim | A | A | A | A | A | A |
| 30 | Al—0.6Ag—0.5Sm | Present | D | 250° C., 30mim | A | A | A | A | A | A |
| 31 | Al—1Ag—1Sm | Present | D | 250° C., 30mim | A | B | B | A | A | A |
| 32 | Al—2Ag—2Sm | Present | D | 250° C., 30mim | A | A | B | A | A | A |
| 33 | Al—6Ag—2Sm | Present | D | 250° C., 30mim | A | B | B | A | A | A |
| 34 | Al—0.1Ag—0.1Ge | Present | D | 250° C., 30mim | A | A | A | A | A | A |
| 35 | Al—0.6Ag—0.5Ge | Present | D | 250° C., 30mim | A | A | A | A | A | A |
| 36 | Al—1Ag—1Ge | Present | D | 250° C., 30mim | A | B | B | A | A | A |
| 37 | Al—2Ag—2Ge | Present | D | 250° C., 30mim | A | B | B | A | A | A |
| 38 | Al—6Ag—2Ge | Present | D | 250° C., 30mim | A | A | B | A | A | A |
| 39 | Al—0.1Ag—0.1Cu | Present | D | 250° C., 30mim | A | A | A | A | A | A |
| 40 | Al—0.6Ag—0.5Cu | Present | D | 250° C., 30mim | A | A | A | A | A | A |
| 41 | Al—1Ag—1Cu | Present | D | 250° C., 30mim | A | A | B | A | A | A |
| 42 | Al—2Ag—2Cu | Present | D | 250° C., 30mim | A | B | B | A | A | A |
| 43 | Al—6Ag—2Cu | Present | D | 250° C., 30mim | A | B | B | A | A | A |
| 44 | Al—0.6Ag—0.5Cu—0.5Nd | Present | D | 250° C., 30mim | A | A | B | A | A | A |
| 45 | Al—0.6Ag—0.5Ge—0.5Nd | Present | D | 250° C., 30mim | A | A | B | A | A | A |

*Unit of composition of components: % by atom, Balance: Al and inevitable impurities
**Inclusion means any inclusion containing elements X, and the hyphen “—” means that the measurement was not carried out because no elements X were added.

Table 3 (the samples obtained with pre-annealing and without post-annealing) and Table 4 (the samples obtained with pre-annealing and post-annealing) show that the use of the Al alloy film satisfying the requirements according to the invention resulted in good results in the work function, the reflectance, the electrical resistivity and the heat resistance as well as in the contact resistance and the alkali corrosion resistance similarly to the results described in Tables 1 and 2, irrespective of the heat treatment conditions.

Referring to Tables 3 and 4, the samples Nos. 3 to 7 involved an Al—Ag alloy containing Ag alone in the amount according to the invention. Similarly to the results described in Table 2 (the samples obtained without pre-annealing and with post-annealing), these samples showed a decreased heat resistance and a decreased alkali corrosion resistance which are properties achieved according to a preferred embodiment of the invention. From these results, it is recommended that pre-annealing or post-annealing be not carried out when the Al—Ag alloy contains no elements X and high heat resistance and high alkali corrosion resistance are needed.

### EXAMPLE 3

In this example, the influence of the thickness of ITO film on the reflectance was studied.

In detail, reflective films were produced in the same manner as described in EXAMPLE 1, grouped into Group A and Group B, and treated in the same manner as described in EXAMPLE 1. The thickness of the ITO film was varied from 5 to 50 nm by changing the sputtering time. For comparison, similar processing was performed using a pure Al film or an Al-0.6% by atom Nd which was a simulated alloy film according to PTL 1.

The reflective anode electrodes manufactured as described above were tested in the same manner as described in EXAMPLE 1 in order to evaluate the reflectance. The results are described in Tables 5 and 6.

TABLE 5

| | Composition of | | ITO film | Post- | Reflect- |
|---|---|---|---|---|---|
| No. | reflective film* | Group | thickness | annealing | ance |
| 1 | Pure Al | A | 5 nm | No | A |
| 2 | Pure Al | A | 10 nm | No | A |
| 3 | Pure Al | A | 30 nm | No | B |
| 4 | Pure Al | A | 50 nm | No | C |
| 5 | Al—0.6Nd | A | 5 nm | No | A |
| 6 | Al—0.6Nd | A | 10 nm | No | A |
| 7 | Al—0.6Nd | A | 30 nm | No | B |
| 8 | Al—0.6Nd | A | 50 nm | No | C |
| 9 | Al—0.6Ag | A | 5 nm | No | A |
| 10 | Al—0.6Ag | A | 10 nm | No | A |
| 11 | Al—0.6Ag | A | 30 nm | No | B |
| 12 | Al—0.6Ag | A | 50 nm | No | C |
| 13 | Al—0.6Ag—0.5Nd | A | 5 nm | No | A |
| 14 | Al—0.6Ag—0.5Nd | A | 10 nm | No | A |
| 15 | Al—0.6Ag—0.5Nd | A | 30 nm | No | B |
| 16 | Al—0.6Ag—0.5Nd | A | 50 nm | No | C |

*Unit of composition of components: % by atom, Balance: Al and inevitable impurities

TABLE 6

| | Composition of | | ITO film | Post-annealing | |
|---|---|---|---|---|---|
| No. | reflective film* | Group | thickness | temperature | Reflectance |
| 1 | Pure Al | B | 5 nm | 250° C., 30mim | A |
| 2 | Pure Al | B | 10 nm | 250° C., 30mim | A |
| 3 | Pure Al | B | 30 nm | 250° C., 30mim | B |
| 4 | Pure Al | B | 50 nm | 250° C., 30mim | C |
| 5 | Al—0.6Nd | B | 5 nm | 250° C., 30mim | A |
| 6 | Al—0.6Nd | B | 10 nm | 250° C., 30mim | A |
| 7 | Al—0.6Nd | B | 30 nm | 250° C., 30mim | B |
| 8 | Al—0.6Nd | B | 50 nm | 250° C., 30mim | C |
| 9 | Al—0.6Ag | B | 5 nm | 250° C., 30mim | A |
| 10 | Al—0.6Ag | B | 10 nm | 250° C., 30mim | A |
| 11 | Al—0.6Ag | B | 30 nm | 250° C., 30mim | B |
| 12 | Al—0.6Ag | B | 50 nm | 250° C., 30mim | C |
| 13 | Al—0.6Ag—0.5Nd | B | 5 nm | 250° C., 30mim | A |
| 14 | Al—0.6Ag—0.5Nd | B | 10 nm | 250° C., 30mim | A |
| 15 | Al—0.6Ag—0.5Nd | B | 30 nm | 250° C., 30mim | B |
| 16 | Al—0.6Ag—0.5Nd | B | 50 nm | 250° C., 30mim | C |

*Unit of composition of components: % by atom, Balance: Al and inevitable impurities

Referring to Tables 5 and 6, the samples Nos. 9 to 11 and Nos. 13 to 15 which involved an Al alloy satisfying the composition according to the invention achieved a high reflectance as a result of controlling the thickness of the ITO film so as to be within the preferred range (30 nm or less). Similar tendencies were observed irrespective of the heat treatment conditions or the composition of the Al alloy forming the reflective film. Such results probably indicate that the reflective properties are affected more strongly by the interference of light between the surface of the Al alloy film and the surface of the ITO film, rather than by the composition of the Al alloy or the heat treatment conditions.

Although the present invention has been described in detail with reference to some specific embodiments, the person skilled in the art will understand that various changes or modifications are possible without departing the spirit and the scope of the present invention.

The present application is based on a Japanese patent application filed in the Japanese Patent Office on Nov. 16, 2009 (Japanese Patent Application No. 2009-261281), the entire contents of which are incorporated herein by reference.

### INDUSTRIAL APPLICABILITY

According to the present invention, the Al—Ag alloy film containing a specific amount of Ag is used as the Al-based alloy reflective film. With this configuration, there can be provided the reflective anode electrode in which the Al reflective film is in direct contact with the oxide conductive film such as ITO or IZO while ensuring a low contact resistance and a high reflectance and in which the multilayer structure having the reflective film and the oxide conductive film (upper layer=oxide conductive film/lower layer=Al-based alloy) exhibits a work function of the surface of the upper oxide conductive film that is as high as the work function of the surface of an upper oxide conductive film in a general multilayer structure having an Ag-based alloy film (upper layer=oxide conductive film/lower layer=Ag-based alloy). The reflective anode electrode according to the invention enables holes to be injected efficiently into an organic emitting layer, and can efficiently reflect the light emitted from the organic emitting layer by the reflective film. Thus, the inventive reflective anode electrode enables an organic EL display to exhibit excellent emission brightness properties.

Further, the Al-based alloy reflective film may contain Ag and a specific amount of at least one element selected from La, Ce, Nd, Y, Sm, Ge, Gd and Cu (hereinafter, sometimes collectively referred to as X). The use of such an Al-Ag-X alloy film results in a reflective anode electrode for organic EL display which is also increased in terms of alkali corrosion resistance and heat resistance.

### REFERENCE SIGNS LIST

SUBSTRATE

TFT

PASSIVATION FILM

PLANARIZATION LAYER

CONTACT HOLE

Al ALLOY FILM (REFLECTIVE FILM)

OXIDE CONDUCTIVE FILM

ORGANIC EMITTING LAYER

CATHODE ELECTRODE

1. A reflective anode electrode formed on a substrate, the reflective anode electrode having a multilayer structure comprising:
an Al-based alloy film comprising 0.1 to 6 atom % Ag, and
an oxide conductive film in direct contact with the Al-based alloy film.

2. The reflective anode electrode of claim 1, comprising a precipitate or a concentrated layer comprising Ag at an interface between the Al-based alloy film and the oxide conductive film.

3. The reflective anode electrode of claim 1, wherein the Al-based alloy film further comprises at least one element selected from the group consisting of La, Ce, Nd, Y, Sm, Ge, Gd and Cu in a total content of 0.1 to 2 atom %, and when the total content of such an element is 1 atom % or more, the element is present as a precipitate.

4. The reflective anode electrode of claim 1, wherein the oxide conductive film comprises indium tin oxide (ITO).

5. The reflective anode electrode of claim 1, wherein the oxide conductive film has a thickness of 5 to 30 nm.

6. The reflective anode electrode of claim 1, wherein the Al-based alloy film is obtained by a sputtering method or a vacuum deposition method.

7. The reflective anode electrode of claim 1, wherein the Al-based alloy film is electrically connected to a source or drain electrode of a thin film transistor formed on the substrate.

8. A thin film transistor substrate comprising the reflective anode electrode of claim 1.

9. An organic EL display comprising the thin film transistor substrate of claim 8.

10. An Al-based alloy sputtering target comprising 0.1 to 6 atom %, which is suitable for forming the Al-based alloy film of claim 1.

11. The Al-based alloy sputtering target of claim 10, further comprising at least one element selected from the group consisting of La, Ce, Nd, Y, Sm, Ge, Gd and Cu in a total content of 0.1 to 2 atom %.

12. The reflective anode electrode of claim 1, wherein the Al-based alloy film has a thickness of 50 to 300 nm.

13. The reflective anode electrode of claim 1, wherein the Al-based alloy film has a thickness of 100 to 200 nm.

14. The reflective anode electrode of claim 1, wherein the oxide conductive film has a thickness of 10 to 20 nm.

15. The reflective anode electrode of claim 1, wherein the Al-based alloy film further comprises 0.1 to 2 atom % of La.

16. The reflective anode electrode of claim 1, wherein the Al-based alloy film further comprises 0.2 to 0.8 atom % of La.

17. The reflective anode electrode of claim 1, wherein the Al-based alloy film comprises 0.1 to 4 atom % of Ag.

18. The reflective anode electrode of claim 1, wherein the Al-based alloy film further comprises at least one element selected from the group consisting of La, Ce, Nd, Y, Sm, Ge, Gd and Cu in a total content of 0.2 to 0.8 atom %.

19. The reflective anode electrode of claim 3, wherein the Al-based alloy film comprises Cu and Nd.

20. The reflective anode electrode of claim 3, wherein the Al-based alloy film comprises Ge and Nd.
